(19) United States
(12) Patent Application Publication
(10) Pub. No.: US 2024/0162116 A1
(43) Pub. Date: May 16, 2024

(54) STRUCTURES WITH BURIED FLUIDIC CHANNELS

(71) Applicant: GlobalFoundries U.S. Inc., Malta, NY (US)

(72) Inventors: Siva P. ADUSUMILLI, Burlington, VT (US); Mark D. LEVY, Williston, VT (US); Steven M. SHANK, Jericho, VT (US)

(21) Appl. No.: 17/988,335

(22) Filed: Nov. 16, 2022

(51) Int. Cl. H01L 23/473; H01L 29/20; H01L 29/205; H01L 29/66; H01L 29/778

(52) U.S. Cl. CPC H01L 23/473; H01L 29/2003; H01L 29/205; H01L 29/66462; H01L 29/7786

(57) ABSTRACT

The present disclosure relates to semiconductor structures and, more particularly, to structures with buried fluidic channels and methods of manufacture. The structure includes: a semiconductor substrate; a device layer with a gradient profile on the semiconductor substrate; a fluidic channel within the device layer comprising the gradient profile; at least one inlet channel in fluid communication with the fluidic channel; and at least one outlet channel in fluid communication with the fluidic channel.

### BACKGROUND

The present disclosure relates to semiconductor structures and, more particularly, to structures with buried fluidic channels and methods of manufacture.

Under power, a semiconductor device generates heat which can create problems for device operation and, in some case, even damage the device. As an example, excess heat from devices degrades/shifts device performance. It is thus important to extract latent heat from the device.

The heat can be dissipated in different ways including using thermal shunts filled with diamond, heat spreading layers acting as heat sinks and cooling channels. The current methods of dissipating heat, though, each have their own issues. For example, a heatsink creates a thermal gradient, whereas cooling channels result in less area for device and die layouts.

### SUMMARY

In an aspect of the disclosure, a structure comprises: a semiconductor substrate; a device layer with a gradient profile on the semiconductor substrate, the plurality of device layers being over the semiconductor substrate; a fluidic channel within the device layer comprising the gradient profile; at least one inlet channel in fluid communication with the fluidic channel; and at least one outlet channel in fluid communication with the fluidic channel.

In an aspect of the disclosure, a structure comprises: a fluidic channel within an buffer material; at least one inlet channel in fluid communication with the fluidic channel; and at least one outlet channel in fluid communication with the fluidic channel.

In an aspect of the disclosure, a method comprises: forming a plurality of device layers comprising a device layer with a gradient profile over the semiconductor substrate; forming a fluidic channel within the device layer comprising the gradient profile; forming at least one inlet channel in fluid communication with the fluidic channel; and forming at least one outlet channel in fluid communication with the fluidic channel.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a structure with buried fluidic channels, amongst other features in accordance with aspects of the present disclosure.

FIG. 2 shows a structure with buried fluidic channels, amongst other features, in accordance with additional aspects of the present disclosure.

FIG. 3 shows a structure with buried fluidic channels, amongst other features, in accordance with additional aspects of the present disclosure.

FIG. 4 shows a structure with buried fluidic channels, amongst other features, in accordance with additional aspects of the present disclosure.

FIGS. 5A-5F show fabrication processes for manufacturing the structure of FIG. 1, in accordance with aspects of the present disclosure.

### DETAILED DESCRIPTION

The present disclosure relates to semiconductor structures and, more particularly, to structures with buried fluidic channels and methods of manufacture. More specifically, in embodiments, the buried fluidic channels may be provided in a hybrid substrate layer above a bulk semiconductor substrate. The buried fluidic channels may also surround a device, e.g., high-electron-mobility transistor (HEMT). Advantageously, the fluidic channels provide the ability to transport and dissipate heat from a substrate and devices to a heatsink without creating a thermal gradient. The use of the buried fluidic channels also enables denser device and die layouts.

The structures with buried fluidic channels of the present disclosure can be manufactured in a number of ways using a number of different tools. In general, though, the methodologies and tools are used to form structures with dimensions in the micrometer and nanometer scale. The methodologies, i.e., technologies, employed to manufacture the devices with buried fluidic channels of the present disclosure have been adopted from integrated circuit (IC) technology. For example, the structures are built on wafers and are realized in films of material patterned by photolithographic processes on the top of a wafer. In particular, the fabrication of the devices with buried fluidic channels uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

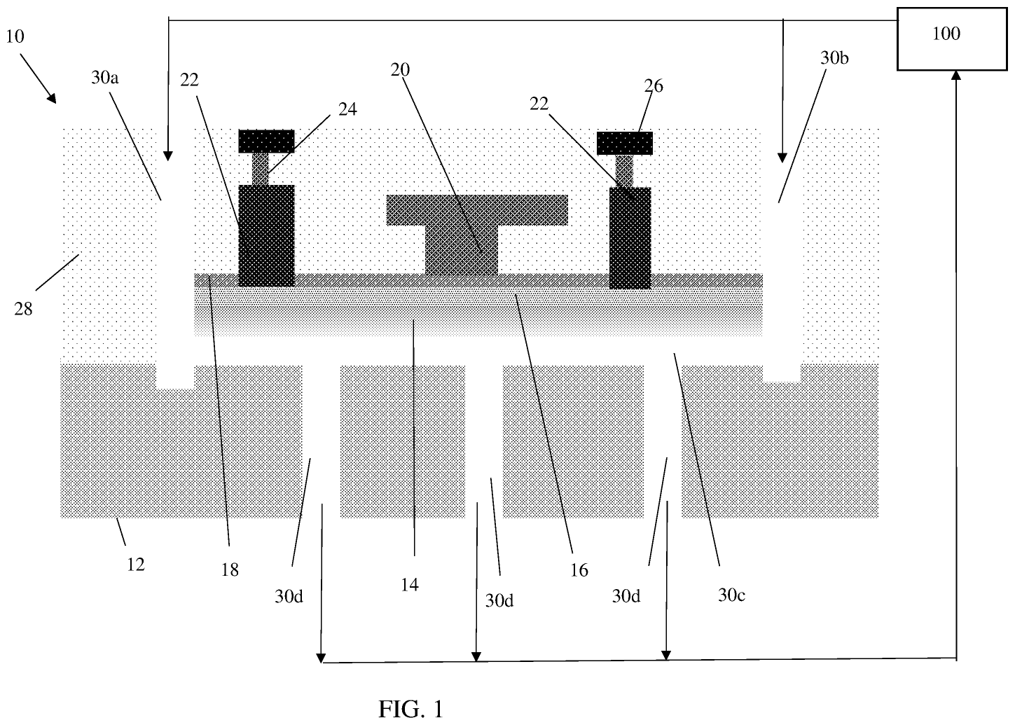

FIG. 1 shows a structure with buried fluidic channels, amongst other features, in accordance with aspects of the present disclosure. More specifically, the structure 10 of FIG. 1 shows a semiconductor substrate 12 with device layers 14, 16, 18 formed on the semiconductor substrate 12. In embodiments, the semiconductor substrate 12 may be a bulk substrate with a <111> crystalline orientation. In more specific embodiments, the semiconductor substrate 12 may an Si substrate with a <111> crystalline orientation. In alternative embodiments, the semiconductor substrate 12 may be composed of any suitable material including, but not limited to, Si, SiGe, SiGeC, SiC, GaAs, InAs, InP, and other III/V or II/VI compound semiconductors. The device layers 14, 16, 18 may form a III-V (GaN) device, e.g., HEMT.

The device layer 14 may be a buffer layer deposited (e.g., epitaxially grown) on the semiconductor substrate 12. In embodiments, the buffer layer 14 may be a semiconductor material with a gradient concentration or profile of different materials, e.g., comprising GaN and AlGaN. More specifically, the buffer layer 14 may be an amorphous graded AlGaN/GaN layer. In embodiments, the buffer layer 14 may be Al rich as it nears the semiconductor substrate 12. For example, the buffer layer 14 may have a graded concentration of AlGaN as it nears the semiconductor substrate 12, along its depth. In this way, the buffer layer 14, e.g., AlGaN, may be selectively etched to form a microfluidic channel 30c as described in more detail herein. The device layer 16 may be GaN (e.g., pure GaN) and the device layer 18 may be AlGaN.

Still referring to FIG. 1, a gate metal 20 may be formed on and in contact with the device layer 18. In embodiments, the gate metal 20 may be, for example, Ti, TiAlC, Al, TiAl, TaN, TaAlC, or TiN; although other gate metals are contemplated herein. Source and drain contacts 22 may be formed in contact with the device layer 16. The source and drain contacts 22 may comprise any appropriate metal, e.g., Al, etc. The source and drain contacts 22 electrically connect to wiring structures 26 through vias 24 (e.g., back end of the line (BEOL) structures known to those of skill in the art). The gate metal 20, source and drain contacts 22, wiring structures 26 and vias 24 may be formed in a dielectric material 28. The dielectric material 28 may be interlevel dielectric material comprising alternate layers of SiN and SiO₂, as examples.

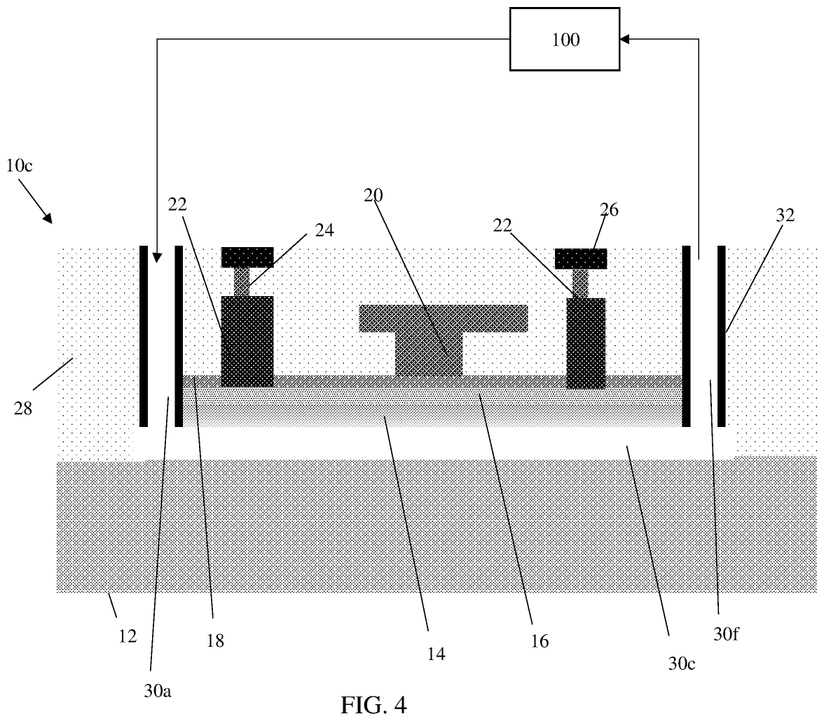

FIG. 1 further shows microfluidic channels 30a, 30b, 30c, 30d formed within the structure 10. The microfluidic channels 30a, 30b may be intake microfluidic channels symmetrically positioned about the HEMT (e.g., device layers 14, 16, 18). In embodiments, the microfluidic channels 30a, 30b may be vertical channels formed in the dielectric material 28 and etched through the device layers 14, 16, 18. The microfluidic channels 30a, 30b may also optionally extend partially into the semiconductor substrate 12. In this way, the microfluidic channels 30a, 30b may have vertical sidewalls constructed from dissimilar materials including single crystal Si, SiO₂, and amorphous graded AlGaN/GaN. As further shown in FIG. 4, for example, the microfluidic channels 30a, 30b may be coated with a sidewall material 32 (e.g., oxide).

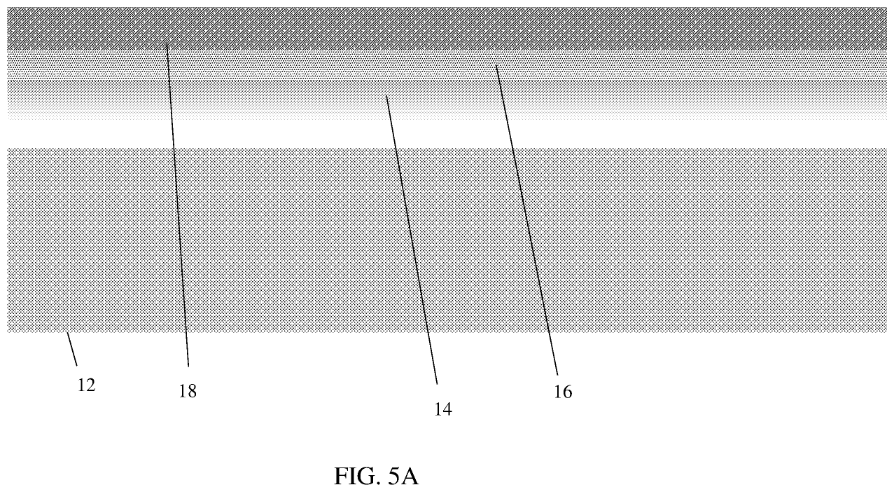

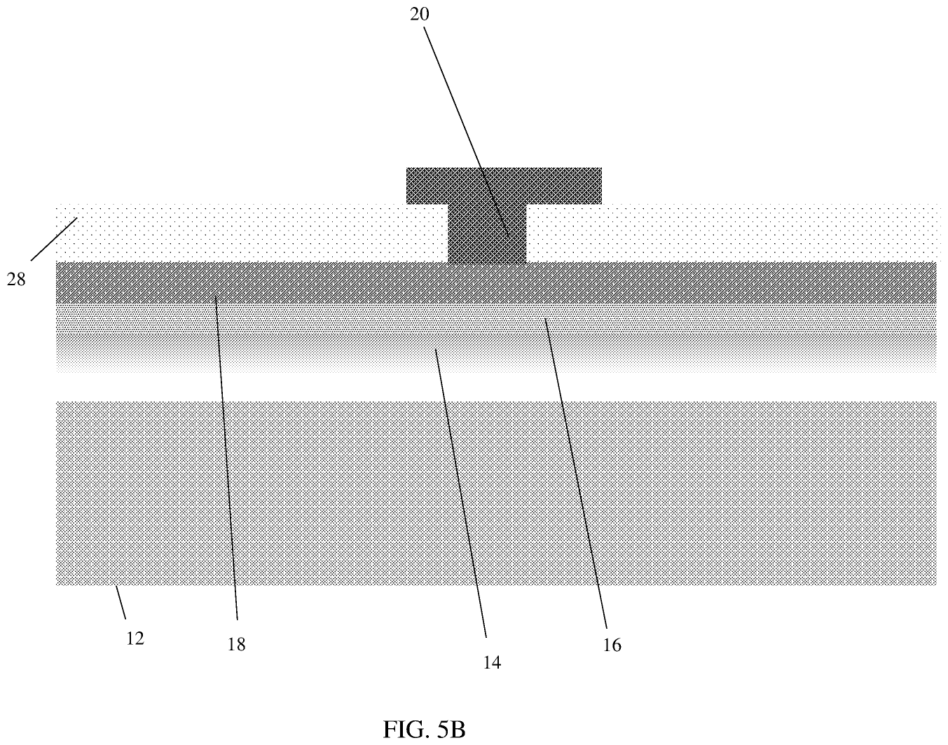

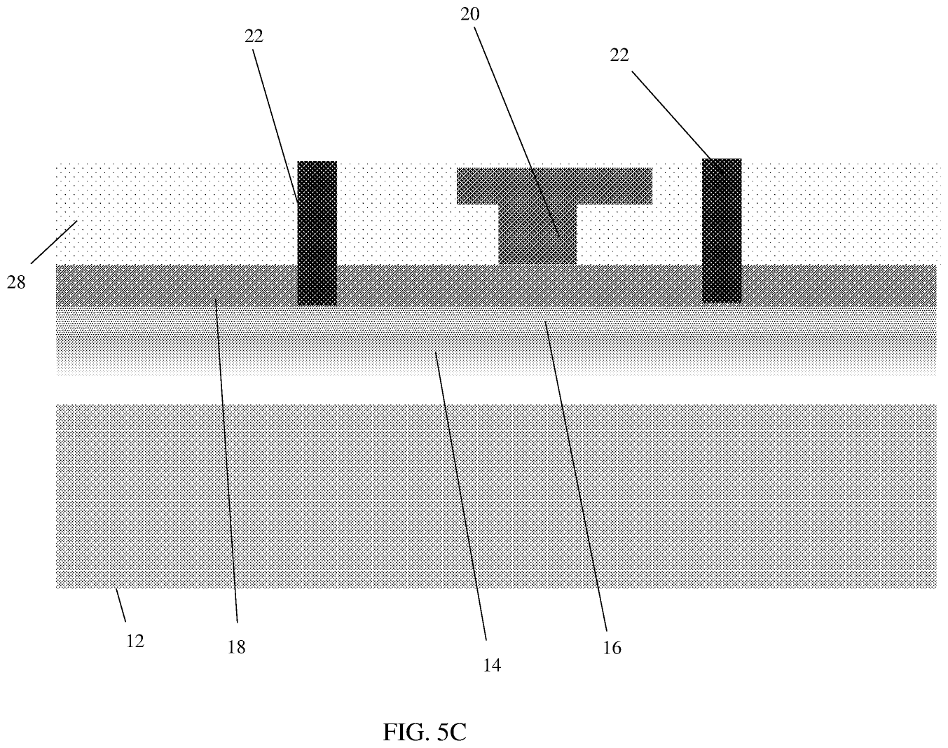

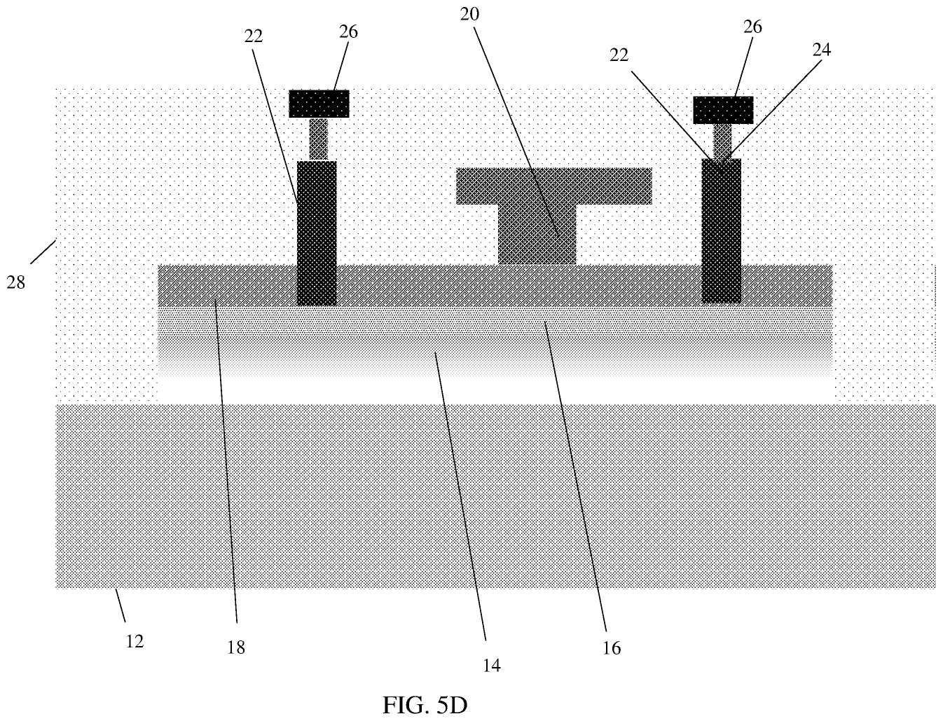

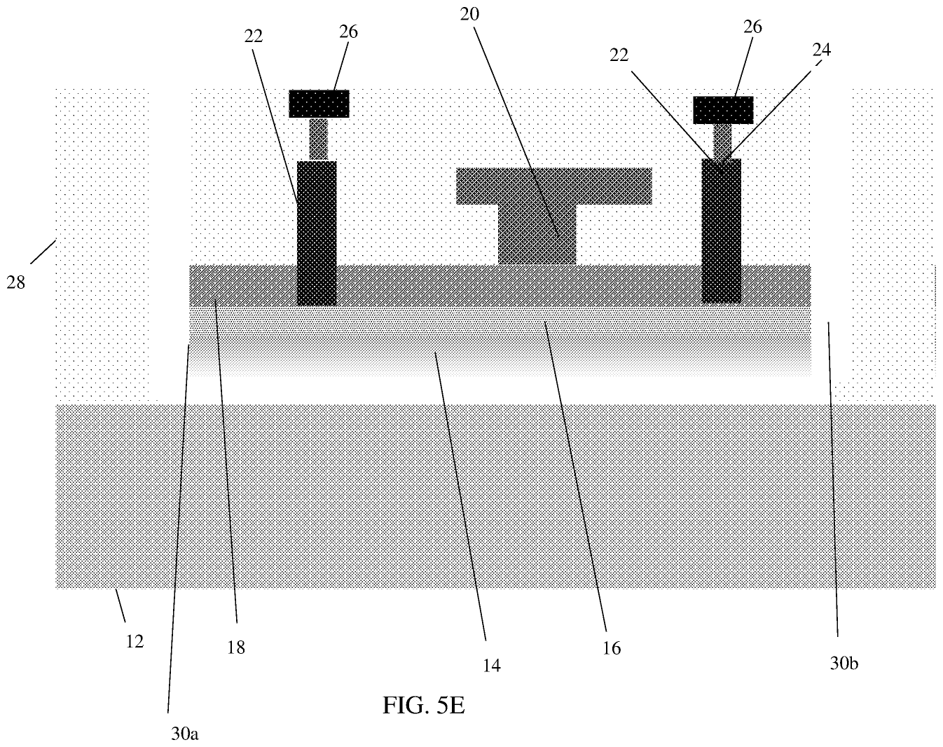

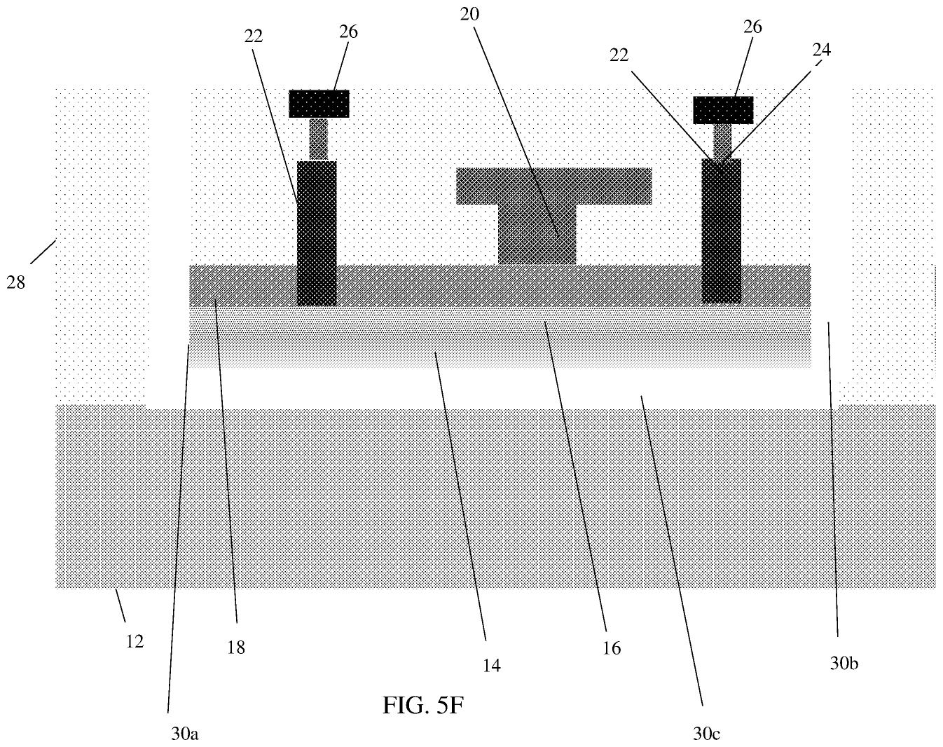

The microfluidic channel 30c may be in fluid communication with the microfluidic channels 30a, 30b. In embodiments, the microfluidic channel 30c may be formed within an Al rich portion of the buffer layer 14 using a selective etching process. More specifically, the microfluidic channel 30c may be a channel etched within the graded GaN/AlGaN buffer layer 14 with a bottom portion comprising the semiconductor substrate 12 as described with respect to FIG. 5F. In this way, the microfluidic channel 30c may have lateral channel sidewalls of graded AlGaN/GaN and Si material. Also, the microfluidic channels 30a, 30b, 30c may surround the device layers, e.g., III-V (GaN) device.

The microfluidic channels 30d may be outlet channels in fluid communication with the microfluidic channel 30c. In embodiments, the microfluidic channels 30d may be formed in the semiconductor substrate 12 below the device, with the inlet channels, e.g., microfluidic channels 30a, 30b, extending above the device. The fluidic channels 30a, 30b, 30c, 30d may be in fluid communication with a heat sink in packaging as representatively shown at reference numeral 100 through the inlet and outlet fluidic channels 30a, 30b, 30d. The inlet and outlet fluidic channels 30a, 30b, 30d may be in fluid communication with the heat sink 100 such that liquid can flow in the direction of the respective arrows.

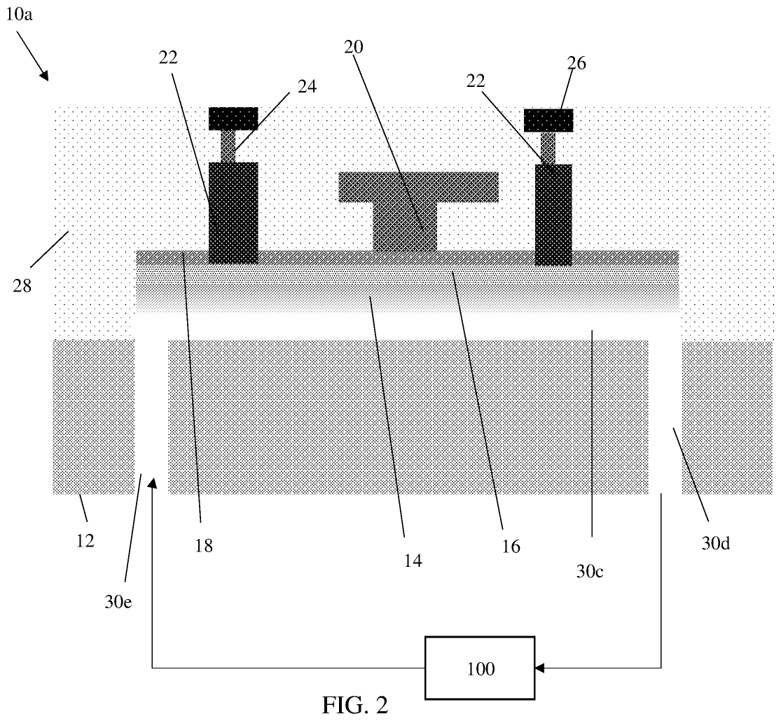

FIG. 2 shows a structure with buried fluidic channels, amongst other features, in accordance with additional aspects of the present disclosure. More specifically, the structure 10a shows the microfluidic channel 30c extending to and in fluid communication with the microfluidic channels 30e, 30d. As in the structure 10 of FIG. 1, the microfluidic channel 30c may be a channel partially etched within the graded GaN/AlGaN buffer layer 14 with a bottom portion of the underlying semiconductor substrate 12. In the structure 10a, though, the microfluidic channel 30e may be the intake channel and the microfluidic channel 30d may be the outlet channel, both of which are in fluid communication with the microfluidic channel 30c and formed in the semiconductor substrate 12 below the device, e.g., device layers 14, 16, 18. Accordingly, in this structure 10a, liquid enters and exits from the bottom of the semiconductor substrate 12. The inlet and outlet fluidic channels 30e, 30d may be in fluid communication with the heat sink 100 such that liquid can flow in the direction of the respective arrows.

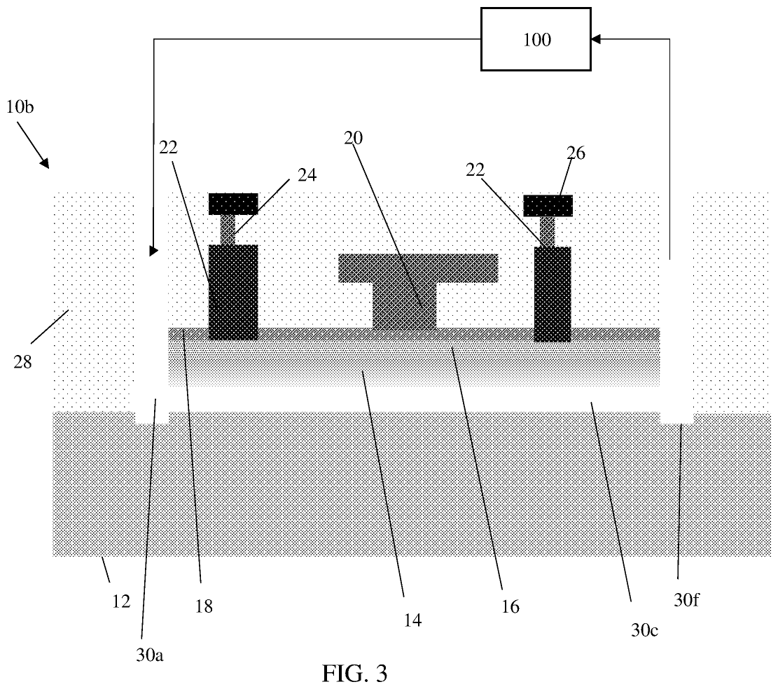

FIG. 3 shows a structure with buried fluidic channels, amongst other features, in accordance with further aspects of the present disclosure. More specifically, the structure 10b shows the microfluidic channel 30c extending to and in fluid communication with the microfluidic channels 30a, 30f. In this embodiment, though, the microfluidic channel 30a may be the intake channel and the microfluidic channel 30f may be the outlet channel, both of which are in fluid communication with the microfluidic channel 30c and symmetrically positioned about the HEMT device (e.g., device layers 14, 16, 18). The inlet and outlet fluidic channels 30a, 30f may be in fluid communication with the heat sink 100 such that liquid can flow in the direction of the respective arrows. Accordingly, in this structure 10b liquid enters and exits from the top of the semiconductor substrate 12.

As in the structure 10 of FIG. 1, the microfluidic channel 30c may be a channel partially etched within the graded GaN/AlGaN buffer layer 14. Also, as in the previous embodiments, the microfluidic channels 30a, 30f may be vertical channels formed in the dielectric material 28 and etched through the device layers 14, 16, 18 resulting in vertical sidewalls constructed from dissimilar materials. The microfluidic channels 30a, 30f may also optionally extend partially into the semiconductor substrate 12.

FIG. 4 shows a structure with buried fluidic channels, amongst other features, in accordance with additional aspects of the present disclosure. More specifically, the structure 10c of FIG. 4 shows the microfluidic channels 30a, 30f coated with a sidewall material 32. In embodiments, the sidewall material 32 may be an oxide. The remaining features are similar to the structure 10b of FIG. 3. In embodiments, the coating 32 avoids lateral attack of active (top) portion of GaN stack (e.g., device layers 14, 16, 18), and especially the AlGaN as an etch rate in a Cl chemistry is proportional to Al content.

FIGS. 5A-5F show fabrication processes for manufacturing the structure 10 of FIG. 1, in accordance with aspects of the present disclosure. More specifically, FIG. 5A shows the device layers 14, 16, 18 formed on the semiconductor substrate 12. In embodiments, the device layers 14, 16, 18 may each be successively epitaxially grown on the semiconductor substrate 12. In embodiments, the first device layer 14 comprises amorphous graded AlGaN/GaN layer with a concentration of Al increasing as it nears the junction of the semiconductor substrate 12. That is, the first device layer 14 includes an Al rich region at the junction of the semiconductor substrate 12.

In FIG. 5B, an insulator material 28 may be formed, e.g., deposited, on the device layers 14, 16, 18, followed by formation of the gate metal 20. The insulator material 28, e.g., SiO₂, may be deposited on the device layer 18 using a conventional deposition method, e.g., chemical vapor deposition (CVD).

In embodiments, the gate metal 20 may be formed by conventional lithography, etching and deposition methods known to those of skill in the art. For example, a resist formed over the insulator material 28 is exposed to energy (light) and developed utilizing a conventional resist developer to form a pattern (opening). An etching process with a selective chemistry, e.g., reactive ion etching (RIE), will be used to transfer the pattern from the photoresist layer to the insulator material 28 to a trench in the insulator material 28 to expose the device layer 18. Following the resist removal by a conventional oxygen ashing process or other known stripants, gate metal can be deposited by any conventional deposition processes, e.g., chemical vapor deposition (CVD) processes. Additional gate metal may be deposited on the insulator material 28, and patterned to form a T-shaped gate metal 20. In embodiments, the gate metal 20 may be formed by a single or dual damascene process as is known in the art.

In FIG. 5C, the source and drain contacts 22 are formed in electrical connection to the device layer 16. The source and drain contacts 22 may be formed by conventional lithography, etching and deposition methods known to those of skill in the art. For example, additional insulator material 28 may be deposited over the gate metal 20, followed by lithography, etching and deposition methods to form the source and drain contacts 22. Any residual material on the surface of the additional insulator material 28 may be removed by a conventional chemical mechanical polishing (CMP) method.

As shown in FIG. 5D, following the formation of the source and drain contacts 22, the device layers 14, 16, 18 may be patterned to form a GaN device. The patterning may be provided by conventional lithography and etching (e.g., RIE) processes as already described herein. Additional insulator material 28 may be deposited over the source and drain contacts 22, sides of the device layers 14, 16, 18 and exposed portions of the semiconductor substrate 12. The back end of line structures, e.g., wiring structures 26 and vias 24, may be formed in electrical and direct contact with the source and drain contacts 22 using conventional lithography and etching processes through the additional insulator material 28, followed by deposition of conductive materials.

FIG. 5E shows microfluidic channels 30a, 30b formed symmetrically about the HEMT (e.g., device layers 14, 16, 18). In embodiments, the microfluidic channels 30a, 30b may be formed by conventional lithography and etching processes with a selective etch chemistry stopping within the device layer 14, and preferably exposing the AlGaN material, e.g., Al rich portion of the AlGaN material, of the buffer layer 14. Accordingly, in this process, the microfluidic channels 30a, 30b are formed in the device layers 14, 16, 18.

In FIG. 5F, the microfluidic channel 30c is formed in fluid communication with the microfluidic channels 30a, 30b. In embodiments, the microfluidic channel 30c may be formed within the buffer layer 14, e.g., Al rich portion of the buffer layer 14, using an etching process with a chemistry selective to Al. More specifically, the microfluidic channel 30c may be a channel etched within the Al rich portion of the buffer layer 14 using a chemistry that is selective to AlGaN and more specifically, Al. In this way, the microfluidic channel 30c may have lateral channel sidewalls of graded AlGaN/GaN and Si material of the semiconductor substrate 12 under the device layer 14, e.g., III-V (GaN) device.

Referring back to FIG. 1, the backside of the semiconductor substrate 12 may be thinned by, for example, a CMP process. Trenches can be formed in the backside of the semiconductor substrate 12 to form the microfluidic channels 30d in fluid connection with the microfluidic channels 30c. The trenches may be formed by conventional lithography and etching processes as already described herein.

The structures with buried fluidic channels can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a semiconductor substrate;
a device layer with a gradient profile on the semiconductor substrate;
a fluidic channel within the device layer comprising the gradient profile;
at least one inlet channel in fluid communication with the fluidic channel; and
at least one outlet channel in fluid communication with the fluidic channel.

2. The structure of claim 1, wherein the at least one outlet channel extends within the semiconductor substrate and the at least one inlet channel extends above the device layer.

3. The structure of claim 2, wherein the at least one inlet channel comprises a sidewall of different materials including the device layer.

4. The structure of claim 2, wherein the device layer comprises a buffer layer.

5. The structure of claim 4, wherein the buffer layer comprises a gradient profile with an Al rich layer, and the fluidic channel is within the Al rich layer.

6. The structure of claim 3, wherein the at least one inlet channel comprises a plurality of inlet channels and, with the fluidic channel, surround a device comprising the device layer.

7. The structure of claim 6, wherein the plurality of inlet channels is symmetrical about the device.

8. The structure of claim 1, wherein the fluidic channel comprises lateral sidewalls of the semiconductor substrate and the device layer.

9. The structure of claim 1, wherein the at least one inlet channel and the at least one outlet channel are within the semiconductor substrate below the device layer.

10. The structure of claim 1, wherein the at least one inlet channel and the at least one outlet channel extend above the device layer in at least a dielectric material.

11. The structure of claim 1, wherein the at least one inlet channel and the at least one outlet channel include a sidewall of dielectric material.

12. A structure comprising:
a fluidic channel within a buffer material;
at least one inlet channel in fluid communication with the fluidic channel; and
at least one outlet channel in fluid communication with the fluidic channel.

13. The structure of claim 12, wherein the at least one outlet channel is within a semiconductor substrate and the at least one inlet channel extends above the fluidic channel.

14. The structure of claim 12, wherein the at least one inlet channel comprises sidewalls of different materials.

15. The structure of claim 12, wherein the at least one inlet channel and the at least one outlet channel are within a semiconductor substrate below the fluidic channel.

16. The structure of claim 12, wherein the buffer material comprises a gradient concentration comprising AlGaN/GaN, the fluidic channel is provided within an Al rich portion of the buffer layer, and the fluidic channel comprises lateral sidewalls of semiconductor substrate and the AlGaN/GaN.

17. The structure of claim 16, wherein the at least one inlet channel comprises a plurality of inlet channels symmetrical about the AlGaN/GaN.

18. The structure of claim 16, wherein the at least one inlet channel and the at least one outlet channel extend above a device in at least a dielectric material.

19. The structure of claim 12, wherein the at least one inlet channel and the at least one outlet channel include a sidewall of dielectric material.

20. A method comprising:
forming a device layer with a gradient profile;
forming a fluidic channel within the device layer comprising the gradient profile;
forming at least one inlet channel in fluid communication with the fluidic channel; and
forming at least one outlet channel in fluid communication with the fluidic channel.
